(19) United States
(12) Patent Application Publication
(10) Pub. No.: US 2020/0286686 A1
(43) Pub. Date: Sep. 10, 2020

(54) FERROELECTRIC CAPACITOR WITH INSULATING THIN FILM

(71) Applicant: Intel Corporation, Santa Clara, CA (US)

(72) Inventors: Chia-Ching Lin, Portland, OR (US); Sou-Chi Chang, Portland, OR (US); Ashish Verma Penumatcha, Hillsboro, OR (US); Nazila Haratipour, Hillsboro, OR (US); Seung Hoon Sung, Portland, OR (US); Owen Y. Loh, Portland, OR (US); Jack Kavalieros, Portland, OR (US); Uygar E. Avci, Portland, OR (US); Ian A. Young, Portland, OR (US)

(73) Assignee: Intel Corporation, Santa Clara, CA (US)

(21) Appl. No.: 16/296,082

(22) Filed: Mar. 7, 2019

(51) Int. Cl. H01G 7/06; H01L 49/02; H01L 27/108

(52) U.S. Cl. CPC H01G 7/06; H01L 27/10805; H01L 28/60; H01L 28/57

(57) ABSTRACT

Described is a ferroelectric-based capacitor that improves reliability of a ferroelectric memory by using low-leakage insulating thin film. In one example, the low-leakage insulating thin film is positioned between a bottom electrode and a ferroelectric oxide. In another example, the low-leakage insulating thin film is positioned between a top electrode and ferroelectric oxide. In yet another example, the low-leakage insulating thin film is positioned in the middle of ferroelectric oxide to reduce the leakage current and improve reliability of the ferroelectric oxide.

### BACKGROUND

Devices such as high charge capacity capacitors (e.g., metal-insulator-metal (MIM) capacitors) for backend can be formed as passive circuit elements or transistors (e.g., metal-oxide-semiconductor (MOS) transistors) for frontend as active circuit elements. Passive circuit elements can be used to provide charge storage and sharing, while active circuit elements can be used to enable low voltage and high current power supply. Traditional ferroelectric capacitors have low retention durations. New materials are desired to make capacitors with longer retentions and higher reliability.

The background description provided here is for the purpose of generally presenting the context of the disclosure. Unless otherwise indicated here, the material described in this section is not prior art to the claims in this application and are not admitted to be prior art by inclusion in this section.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a schematic of a ferroelectric capacitor (FE-Cap).

FIG. 2A illustrates a plot showing charge versus voltage function of the FE-Cap, its memory states, and imprint charge.

FIG. 2B illustrates a plot showing hysteresis property of ferroelectric material.

FIGS. 3A-C illustrate cross-sections of capacitor over bit-line (COB) with insulative oxide layer adjacent to a ferroelectric material, in accordance with some embodiments of the disclosure.

FIGS. 4A-C illustrate cross-sections of metal-insulator-metal (MIM) capacitors with insulative oxide layer adjacent to a ferroelectric material, in accordance with some embodiments of the disclosure.

FIG. 5 illustrates a cross-section of an embedded dynamic random access memory (eDRAM) comprising COB of any one of FIGS. 3A-C, in accordance with some embodiments of the disclosure.

FIG. 6 illustrates an apparatus, which includes a power plane comprising a super capacitor with insulative oxide layer adjacent to a ferroelectric material, according to some embodiments of the disclosure.

FIG. 7 illustrates an apparatus showing distributed MIM capacitors with insulative oxide layer adjacent to a ferroelectric material, according to some embodiments of the disclosure.

FIGS. 8A-B illustrate apparatuses for switch-mode power supply during charging and discharging modes, respectively, according to some embodiments of the disclosure.

FIG. 9 illustrates a 4-terminal controlled switch for the power plane, according to some embodiments of the disclosure.

FIG. 10 illustrates a flowchart of a method for forming an FE capacitor with insulative oxide layer adjacent to a ferroelectric material, in accordance with some embodiments of the disclosure.

FIG. 11 illustrates a smart device, a computer system, or a SoC (System-on-Chip) including capacitor with insulative oxide layer adjacent to a ferroelectric material, in accordance with some embodiments of the disclosure.

### DETAILED DESCRIPTION

Hafnium (Hf) and Zirconium (Zr) based ferroelectric (FE) oxide thin films are promising options for next generation of front-end or back-end embedded dynamic random access memory (DRAM), high-density memory, and metal-insulator-metal (MIM) capacitor due to their scalability. However, for Hf and Zr-based ferroelectric oxide, leakage current is pushing oxygen vacancy re-distribution in the ferroelectric oxide layer, which degrade the ferroelectric polarization response after long endurance cycles. Further, for perovskite-based and lead-based ferroelectric oxide, the leakage current is typically high while scaling down the thickness. As such, existing ferroelectric oxide thin film continue to suffer from reliability issues. Hence, it remains challenging to have over 10¹² endurance cycle at high temperature (e.g., greater than 80 degree C.).

In some embodiments, a MIM capacitor is described which comprises a first structure (e.g., first electrode) comprising metal; and a second structure (e.g., second electrode) comprising metal, a third structure comprising ferroelectric material, wherein the third structure is between and adjacent to the first and second structures; and a fourth structure adjacent to the third structure, wherein the fourth structure comprises insulative material. In some embodiments, the insulative material includes an oxide of one or more of: Al, Ti, Hf, Si, Ir, or N. In some embodiments, the insulative material has a thickness in a range of 5 A (Angstrom) to 100 A. In some embodiments, the MIM capacitor includes a fifth structure adjacent to the first structure, wherein the fifth structure comprises a barrier material, which includes Ta and N. In some embodiments, the MIM capacitor includes a sixth structure adjacent to the fifth structure such that the fifth structure is between the first and sixth structures, wherein the sixth structure comprises metal including one or more of: Cu, Al, graphene, carbon nanotube, Au, Co, Ti, N. In some embodiments, the ferroelectric material includes one or more of: Hf or Zr. In some embodiments, the ferroelectric material includes one or more of: Pb, Ti, Zr, Ba, N Si, La, Al, or Hf. In some embodiments, the ferroelectric material has a thickness in a range of 2 nm (nanometer) to 20 nm. In some embodiments, the ferroelectric material is a super lattice of a first material and a second material, wherein the first material includes one of: PbTiO₃ (PTO), SrZrO₃, or FeO3, and wherein the second material includes one of: SrTiO₃ (STO), BaZrO₃, or YTiO₃.

By using a low-leakage insulating thin film between the bottom electrode and the ferroelectric oxide, between the top electrode and the ferroelectric oxide, or in the middle of the ferroelectric oxide, leakage current is reduced and reliability of the ferroelectric oxide is improved. This low-leakage insulating thin film results in an efficient way to control the leakage current without changing the property e.g., (memory window and annealing temperature) of the ferroelectric oxide. As such, larger arrays of low power memory bit-cells can be realized. Further, such low-leakage capacitors can also be used as super capacitors to provide power to one or more electronic devices. Other technical effects will be evident from the various embodiments and figures.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “adjacent” here generally refers to a position of a thing being next to (e g , immediately next to or close to with one or more things between them) or adjoining another thing (e.g., abutting it).

The term “circuit” or “module” may refer to one or more passive and/or active components that are arranged to cooperate with one another to provide a desired function.

The term “signal” may refer to at least one current signal, voltage signal, magnetic signal, or data/clock signal. The meaning of “a,” “an,” and “the” include plural references. The meaning of “in” includes “in” and “on.”

The term “scaling” generally refers to converting a design (schematic and layout) from one process technology to another process technology and subsequently being reduced in layout area. In some case, scaling to another process technology node also results into upsizing devices and their layout. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

Here, multiple non-silicon semiconductor material layers may be stacked within a single fin structure. The multiple non-silicon semiconductor material layers may include one or more “P-type” layers that are suitable (e.g., offer higher hole mobility than silicon) for P-type transistors. The multiple non-silicon semiconductor material layers may further include one or more “N-type” layers that are suitable (e.g., offer higher electron mobility than silicon) for N-type transistors. The multiple non-silicon semiconductor material layers may further include one or more intervening layers separating the N-type from the P-type layers. The intervening layers may be at least partially sacrificial, for example to allow one or more of a gate, source, or drain to wrap completely around a channel region of one or more of the N-type and P-type transistors. The multiple non-silicon semiconductor material layers may be fabricated, at least in part, with self-aligned techniques such that a stacked CMOS device may include both a high-mobility N-type and P-type transistor with a footprint of a single finFET.

Here, the term “backend” generally refers to a section of a die which is opposite of a “frontend” and where an IC (integrated circuit) package couples to IC die bumps. For example, high-level metal layers (e.g., metal layer 6 and above in a ten-metal stack die) and corresponding vias that are closer to a die package are considered part of the backend of the die. Conversely, the term “frontend” generally refers to a section of the die that includes the active region (e.g., where transistors are fabricated) and low-level metal layers and corresponding vias that are closer to the active region (e.g., metal layer 5 and below in the ten-metal stack die example).

It is pointed out that those elements of the figures having the same reference numbers (or names) as the elements of any other figure can operate or function in any manner similar to that described, but are not limited to such.

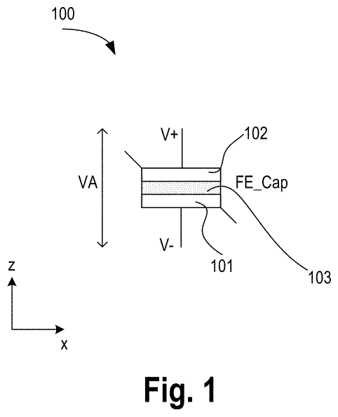

FIG. 1A illustrates a schematic of a ferroelectric capacitor (FE-Cap) 100. FE-cap 100 generally comprises two metal layers 101 and 102 and ferroelectric material (e.g., FE oxide) 103 coupled between them. Unlike a normal dielectric based capacitor, a ferroelectric capacitor uses polarization charge to store the memory states, where positive and negative polarization charge indicates state “1” or “0”. Here, metal layer 101 is a bottom electrode and metal layer 102 is a top electrode. Ferroelectric material 103 is typically Hf and Zr-based ferroelectric oxide. However, leakage current is pushing oxygen vacancy re-distribution in the oxide FE oxide, which degrade the polarization response of the FE oxide after long endurance cycles. For perovskite-based and lead-based ferroelectric oxide material 103, the leakage current is typically high while scaling down the thickness. As such, existing ferroelectric oxide thin film 103 continue to suffer from reliability issues. Hence, it is challenging to have over 10¹² endurance cycle at high temperature (e.g., greater than 80 degree C.).

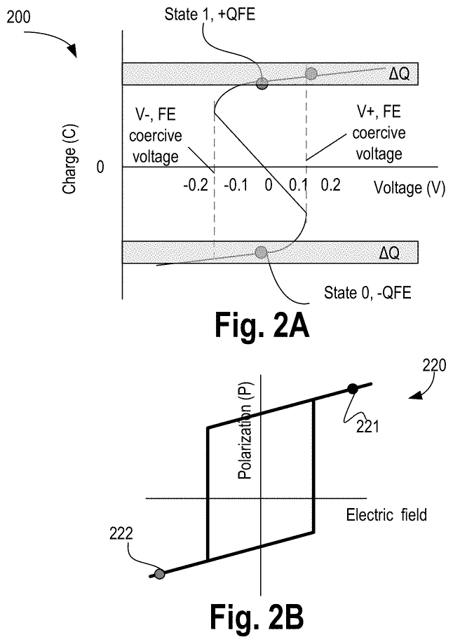

FIG. 2A illustrates plot 200 showing charge versus voltage function of the FE-Cap, its memory states, and imprint charge. Here, x-axis is voltage (V) and y-axis is charge (C). To switch an FE-cap 103, the applied FE-cap voltage VA is be higher than the ferroelectric coercive voltages (which behave as threshold voltages) when driven by a voltage source. For example, VA is greater than V+ for 0 to 1 state switching, and VA is less than V− for 1 to 0 state switching.

FIG. 2B illustrates plot 220 showing hysteresis property of ferroelectric material 103, in accordance with some embodiments. Ferroelectric material 103 exhibits ferroelectricity, which is a property by which a spontaneous electric polarization can be revered by an electric field (e.g., applied voltage). When dielectric materials are polarized, the induced polarization ‘P’ is almost exactly proportional to the applied external electric field E. In such materials, the polarization is a linear function of the applied electric field or voltage. Ferroelectric materials, on the other hand, demonstrate a spontaneous non-zero polarization even when the applied electric field E is zero. As such, the spontaneous polarization can be reversed by an applied electric field in the opposite direction. This results in a hysteresis loop because the polarization of a ferroelectric material is dependent not only on the present electric field but also on its history. The hysteresis loop of plot 220 shows two stable operating positions for FE 103—position 221 and position 222. These two stable positions indicate that the direction of polarization can be switched (e.g., polled) from one to another and this changes the response of polarization to applied AC voltage.

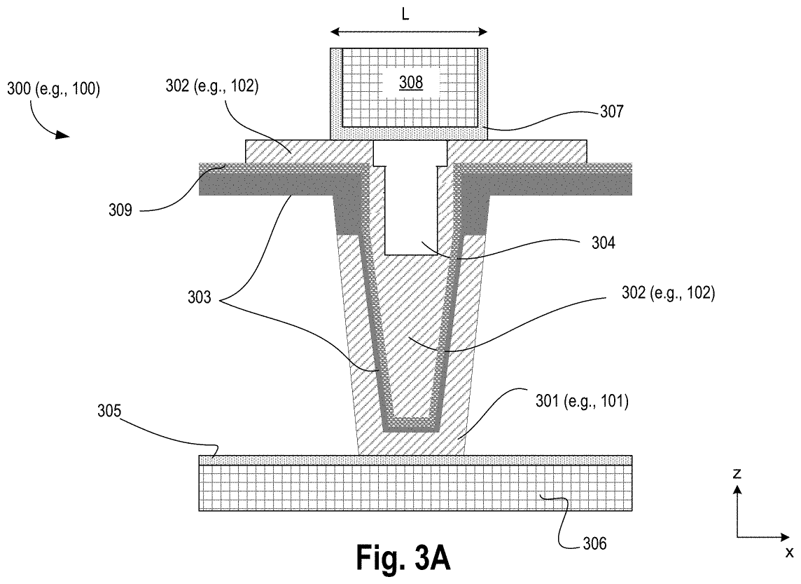

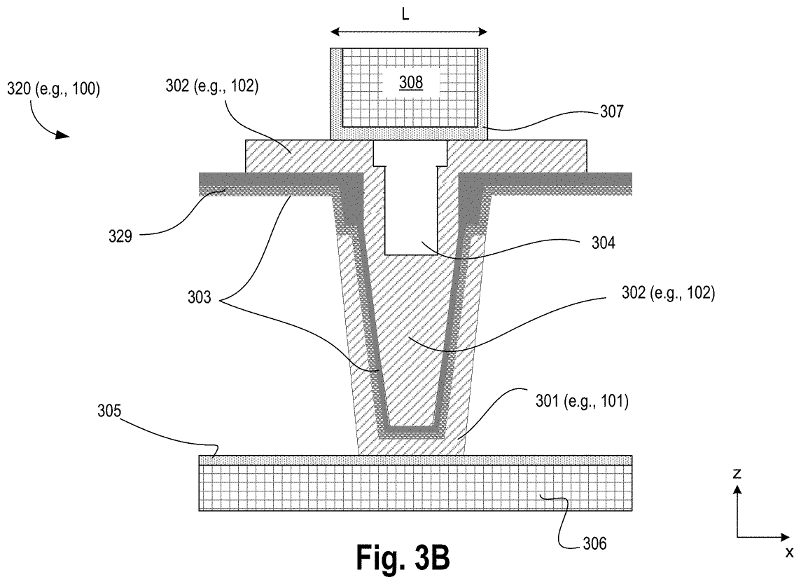

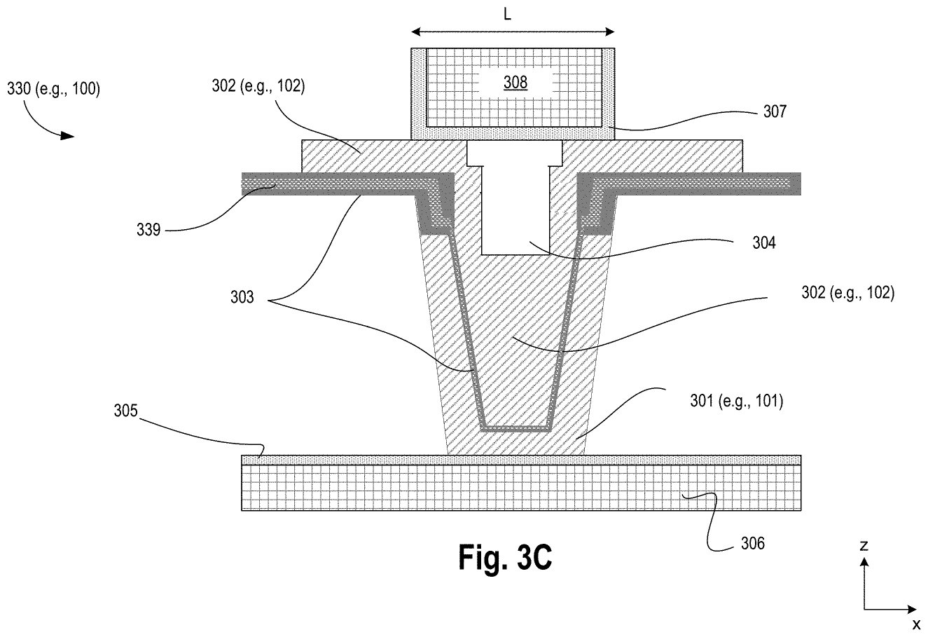

FIG. 3A illustrates a cross-section of a capacitor over bit-line (COB) 300 with insulative oxide layer above a ferroelectric material, in accordance with some embodiments of the disclosure. In some embodiments, COB 300 comprises first electrode 301 (e.g., 101), second electrode 302 (e.g., 102), ferroelectric material 303, metal structure 304, first barrier 305, first interconnect 306, second barrier 307, second interconnect 308, and insulative material 309. Bottom electrode 301 is coupled to first interconnect 306 via a barrier layer 305 while top electrode 304 is coupled to second interconnect 308 via metal via 304 and second barrier 307.

In COB configurations, in various embodiments, stacked memory capacitors are fabricated above an access transistor in the back-end interconnect portion of the process flow. In some embodiments, first and second electrodes 301 and 302, respectively, comprise any metallic materials that have lattice constant smaller than 5.0 A. In some embodiments, first and second electrodes 301 and 302, respectively, comprise metal including one or more of: Cu, Al, graphene, carbon nanotube, Ay, Co, Ti. In various embodiments, first and second electrodes 301 and 302, respectively, comprise material, which can be deposited by atomic layer deposition (ALD).

In various embodiments, ferroelectric material 303 is adjacent to a thin insulative layer 309. In this example, layer 309 is above ferroelectric material 303 such that ferroelectric material 303 is coupled to top electrode 302 via layer 309 while ferroelectric material 303 is directly coupled to bottom electrode 301. In some embodiments, insulative layer 309 comprises an oxide layer. In various embodiments, any low-leakage amorphous/polycrystalline/single crystalline insulating thin film can be used for layer 309. The thickness of layer 309 along the z-axis ranges from 5 A to 100 A. Example material for layer 209 include: Al2O3, TiO2, HfO2, SiNx, or SiO2.

In various embodiments, the low-leakage insulating thin film 309 is inserted between bottom electrode 301 and ferroelectric oxide 303, between top electrode 302 and ferroelectric oxide 303, or in the middle of ferroelectric oxide 303 to reduce the leakage current. Because of low leakage current passing through Hf and Zr-based oxide layer, there is negligible oxygen vacancies re-distribution, which improve reliability of FE oxide 303. For perovskite and lead-based FE oxide 303, with inserting a low leakage oxide thin film the thickness of perovskite is scaled down while achieving low leakage current in FE oxide 303. This is an efficient way to control the leakage current without changing the ferroelectric property (memory window and annealing temperature) in ferroelectric oxide 303.

In some embodiments, ferroelectric material 303 employed in the ferroelectric capacitor 300 may include, for example, materials exhibiting ferroelectric behavior at thin dimensions, such as hafnium or zirconium-based oxide (Hf or Zr-based oxide). The thickness of FE material 103 along the z-axis is in a rage of 2 nm to 20 nm. The ferroelectric material 303 includes materials such as: hafnium zirconium oxide (HfZrO, also referred to as HZO, which includes hafnium, zirconium, and oxygen), silicon-doped (Si-doped) hafnium oxide (which is a material that includes hafnium, oxygen, and silicon), germanium-doped (Ge-doped) hafnium oxide (which is a material that includes hafnium, oxygen, and germanium), aluminum-doped (Al-doped) hafnium oxide (which is a material that includes hafnium, oxygen, and aluminum), yttrium-doped (Y-doped) hafnium oxide (which is a material that includes hafnium, oxygen, and yttrium), lead zirconate titanate (which is a material that includes lead, zirconium, and titanium), barium zirconate titanate (which is a material that includes barium, zirconium and titanium), and combinations thereof. Some embodiments include hafnium, zirconium, barium, titanium, and/or lead, and combinations thereof for FE material 303.

In some embodiments, first and second interconnects 306 and 308 include one or more of: Cu, Al, graphene, CNT, Au, Co, or TiN. In some embodiments, barrier layers 305 and 307 are provided between the interconnects and electrodes. In various embodiments, these barrier layers are diffusion barriers and may comprise TaN. Barrier layers 305 and 307 include one or more of: TaN, graphene, MX2 or M2X, and transition metal dichalcogenides such as MoS2, MoSe2, Cu2S etc. The thickness ‘t’ along the z-axis for barrier layers 305 and 307 is 5 A to 40 A.

FIG. 3B illustrates cross-section of COB 320 with insulative oxide layer 329 below ferroelectric material 303, in accordance with some embodiments of the disclosure. Material for layer 329 is same as the material for layer 309. In this embodiment, ferroelectric material 309 is coupled to bottom electrode 301 through insulative layer 329. Likewise ferroelectric material 309 is directly coupled to top electrode 302.

FIG. 3C illustrates cross-section of COB 330 with insulative oxide layer 329 inside ferroelectric material 303, in accordance with some embodiments of the disclosure. Material for layer 339 is same as the material for layer 309. In this embodiment, ferroelectric material 303 has top and bottom sections such that layer 339 is between the top and bottom sections of ferroelectric 303. Here, the top section of layer 303 is directly coupled to top electrode 302 while the bottom section of layer 303 is directly coupled to bottom electrode 301. Functionally, the COBs of FIGS. 3B-C operate same as COB of FIG. 3A and provide similar technical effect.

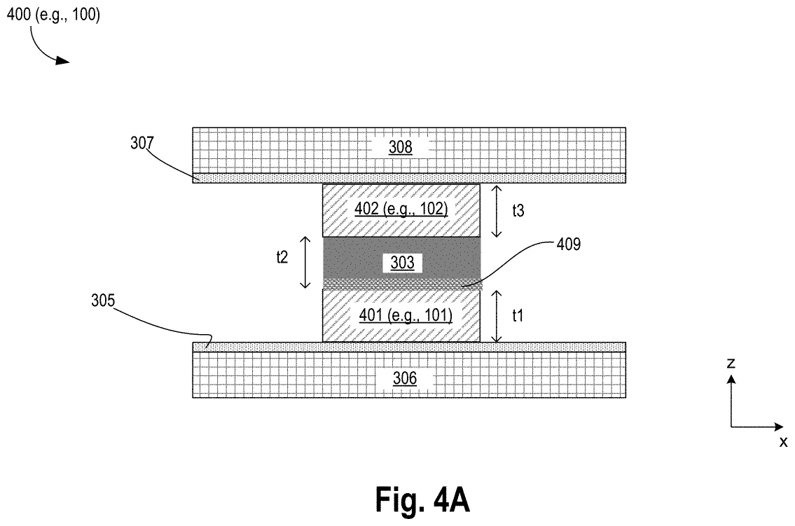

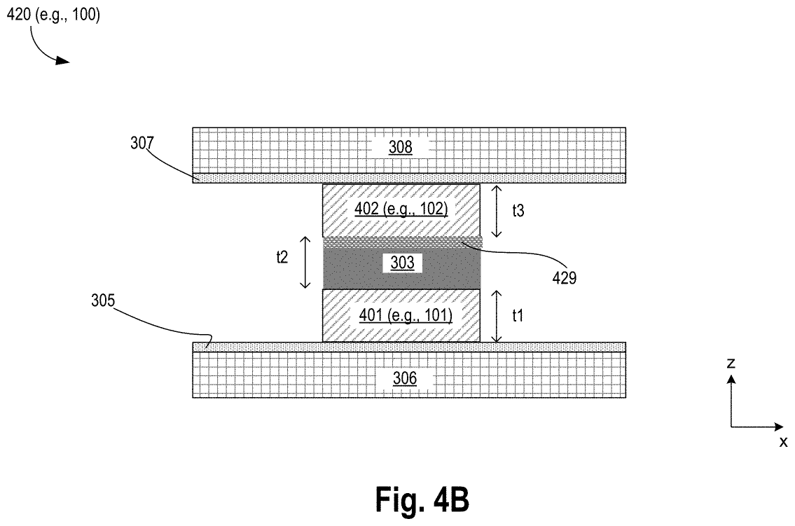

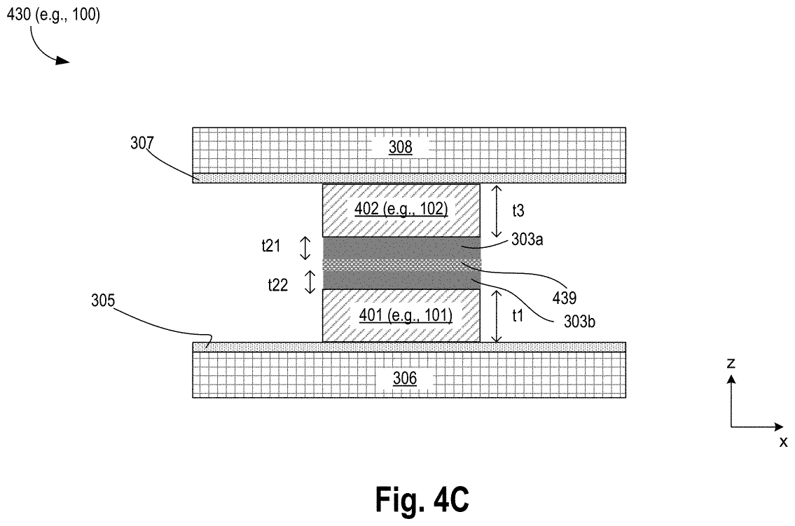

FIG. 4A illustrates a cross-section of MIM capacitor 400 with insulative oxide layer below a ferroelectric material, in accordance with some embodiments of the disclosure. Capacitor 400 has similar material as COB 300. Capacitor 400 comprises first electrode 401 (e.g., 101), second electrode 402 (e.g., 102), ferroelectric material 303, metal structure 304, first barrier 305, first interconnect 306, second barrier 307, second interconnect 308; and insulating material 409 (same material as material 309). The thickness of insulating material 409 along the z-axis is 5 to 10 Angstroms. Material wise, first and second electrodes 401 and 402, respectively, are similar to materials for first and second electrodes 301 and 302, respectively. Capacitor 400 can be used in the frontend or the backend. The thickness t1 and t2 are in a range from 50 A (Angstrom) to 200 A. The thickness t3 is of a range from 20 A to 100 A.

FIG. 4B illustrates cross-section of MIM capacitor 420 with insulative oxide layer above a ferroelectric material, in accordance with some embodiments of the disclosure. Material for layer 429 is same as the material for layer 409. In this embodiment, ferroelectric material 303 is coupled to top electrode 402 through insulative layer 429. Likewise ferroelectric material 303 is directly coupled to bottom electrode 401. The thickness of insulating material 429 along the z-axis is 5 to 10 Angstroms.

FIG. 4C illustrates a cross-section of MIM capacitor 430 with insulative oxide layer is between ferroelectric material, in accordance with some embodiments of the disclosure. In this embodiment, ferroelectric material 303 has top 303a and bottom 303b sections such that layer 439 is between the top 303a and bottom 303b sections of ferroelectric 303. Here, the top section 303a of layer 303 is directly coupled to top electrode 402 while the bottom section 303b of layer 303 is directly coupled to bottom electrode 401. The thickness of insulating material 439 along the z-axis is 5 to 10 Angstroms. Functionally, the MIMs of FIGS. 4B-C operate same as COB of FIG. 4A and provide similar technical effect. The thickness t21 and t22 are in a range of 10 A to 50 A.

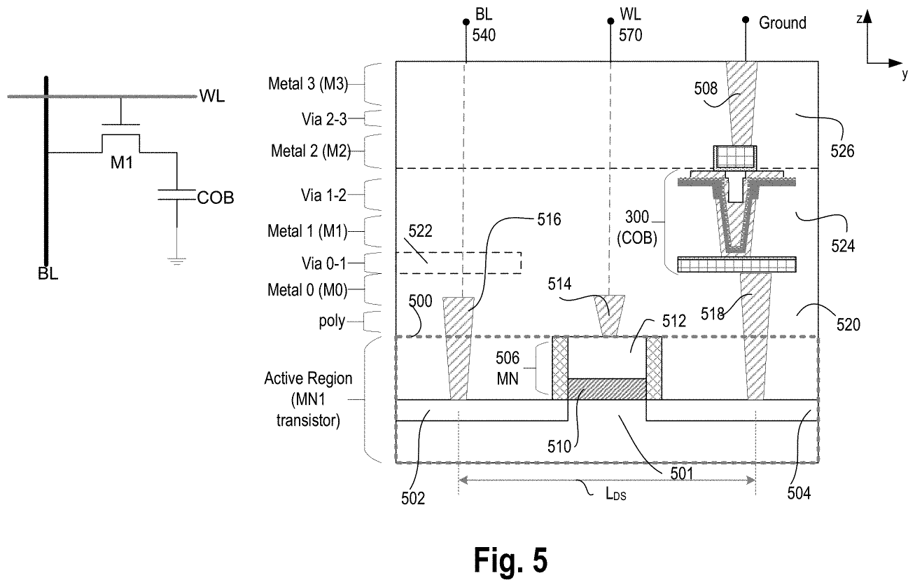

FIG. 5 illustrates a cross-section of an embedded dynamic random access memory (eDRAM) comprising COB of any one of FIGS. 3A-C, in accordance with some embodiments of the disclosure. In some embodiments, transistor 500 has source region 502, drain region 504 and gate 506. Transistor 500 (e.g., n-type transistor M1) further includes gate contact 514 disposed above and electrically coupled to gate 506, source contact 516 disposed above and electrically coupled to source region 502, and drain contact 518 disposed above and electrically coupled to drain region 504. In various embodiments, COB 300, 320, or 330 (or MIM 400, 420, 430) is disposed above transistor 500 such that electrode 308 is coupled to via or metal structure 508A, and electrode 306 is coupled to via 518.

In some embodiments, gate contact 514 is directly below COB 300/320/330 (or MIM 400/420/430). In some embodiments, word-line (WL) contact 570 is disposed onto gate contact 514 on a second y-z plane behind (into the page) first y-z plane metal 522a.

In some embodiments, transistor 500 associated with substrate 501 is a metal-oxide-semiconductor field-effect transistor (MOSFET or simply MOS transistors), fabricated on substrate 501. In various embodiments of the present disclosure, transistor 500 may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. In an embodiment, transistor 500 is a tri-gate transistor.

Here, COB 300, 320, or 330 (or MIM 400, 420, 430) stores data. For simplicity purposes, FIG. 5 is illustrated with reference to COB 300, but other capacitor forms with insulating oxide layer can also be used. Data is written into COB 300 as charge via bit-line (BL) 540 when access transistor M1 is turned on by applying voltage on word-line WL 570.

In some embodiments, the underlying substrate 501 represents a surface used to manufacture integrated circuits. In some embodiments, substrate 501 includes a suitable semiconductor material such as but not limited to, single crystal silicon, polycrystalline silicon and silicon on insulator (SOI). In another embodiment, substrate 501 includes other semiconductor materials such as germanium, silicon germanium, or a suitable group III-V or group III-N compound. Substrate 501 may also include semiconductor materials, metals, dopants, and other materials commonly found in semiconductor substrates.

In some embodiments, transistor 500 includes a gate stack formed of at least two layers, gate dielectric layer 510 and gate electrode layer 512. Gate dielectric layer 510 may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer 510 to improve its quality when a high-k material is used.

Gate electrode layer 512 of transistor 500 is formed on gate dielectric layer 510 and may comprise of at least one P-type work-function metal or N-type work-function metal, depending on whether the transistor is to be a PMOS or an NMOS transistor. In some embodiments, the gate electrode layer 512 may comprise of a stack of two or more metal layers, where one or more metal layers are work-function metal layers and at least one metal layer is a conductive fill layer.

For a PMOS transistor, metals that may be used for gate electrode layer 512 include, but are not limited to, ruthenium, palladium, platinum, cobalt, nickel, and conductive metal oxides, e.g., ruthenium oxide. A P-type metal layer will enable the formation of a PMOS gate electrode layer 512 with a work-function that is between about 4.9 eV and about 5.2 eV. For an NMOS transistor, metals that may be used for gate electrode layer 512 include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of NMOS gate electrode layer 512 with a work-function that is between about 3.9 eV and about 4.2 eV.

In some embodiments, gate electrode layer 512 may comprise a “U”-shaped structure that includes a bottom portion substantially parallel to the surface of the substrate and two sidewall portions that are substantially perpendicular to the top surface of the substrate. In another embodiment, at least one of the metal layers that form gate electrode layer 512 may simply be a planar layer that is substantially parallel to the top surface of the substrate and does not include sidewall portions substantially perpendicular to the top surface of the substrate. In some embodiments of the present disclosure, the gate electrode layer 512 may comprise of a combination of U-shaped structures and planar, non-U-shaped structures. For example, gate electrode layer 512 may comprise of one or more U-shaped metal layers formed atop one or more planar, non-U-shaped layers.

In some embodiments, a pair of gate dielectric layer 510 may be formed on opposing sides of the gate stack that bracket the gate stack. Gate dielectric layer 510 may be formed from a material such as silicon nitride, silicon oxide, silicon carbide, silicon nitride doped with carbon, and silicon oxynitride. Processes for forming sidewall spacers are well known in the art and generally include deposition and etching process operations. In some embodiments, a plurality of spacer pairs may be used, for instance, two pairs, three pairs, or four pairs of sidewall spacers may be formed on opposing sides of the gate stack.

In some embodiments, source region 502 and drain region 504 are formed within the substrate adjacent to the gate stack of transistor 500. Source region 502 and drain region 504 are generally formed using either an implantation/diffusion process or an etching/deposition process. In the former process, dopants such as boron, aluminum, antimony, phosphorous, or arsenic may be ion-implanted into the substrate to form the source region 502 and drain region 504. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate source region 502 and drain region 504. In some embodiments, the source region 502 and drain region 504 may be fabricated using a silicon alloy such as silicon germanium or silicon carbide. In some embodiments, the epitaxially deposited silicon alloy may be doped in-situ with dopants such as boron, arsenic, or phosphorous. In some embodiments, source region 502 and drain region 504 may be formed using one or more alternate semiconductor materials such as germanium or a suitable group III-V compound. In some embodiments, one or more layers of metal and/or metal alloys may be used to form source region 502 and drain region 504.

In some embodiments, gate contact 514 and drain contact 518 of the transistor 500 are disposed in first dielectric layer 520 disposed above substrate 501. In some embodiments, terminal B is disposed in second dielectric layer 522 disposed on first dielectric layer 520. In some embodiments, third dielectric layer 524 is disposed on the second dielectric layer 522. In some embodiments, fourth dielectric layer 526 is disposed on third dielectric layer 524. In some embodiments, source contact 516 is partially disposed in fourth dielectric layer 526, partially disposed in the third dielectric layer 524, partially disposed in second dielectric layer 522 and partially disposed on the first dielectric layer 520. In some embodiments, terminal B contact is disposed in third dielectric layer 524. In some embodiments, the conductive interconnect structure such as conductive interconnect structure 508 disposed in fourth dielectric layer 526.

In the illustrated embodiment of FIG. 5, gate contract 514 is formed in poly region; drain contract 518 is formed in active, poly, and Metal 0 (M0); electrode 306 is formed in Via 0-1 layer; COB 300 is formed in Metal 1 (M1) and Via 1-2; electrode 308 is formed in Metal 2 (M2), and conductor 508 is formed in Via 2-3 and Metal (M3). In some embodiments, COB 300 is formed in the metal 3 (M3) region.

In some embodiments, an n-type transistor M1 is formed in the frontend of the die while COB 300 is located in the backend of the die. In some embodiments, COB 300 is located in the backend metal layers or via layers for example in Via 3. In some embodiments, the electrical connectivity to the device is obtained in layers M0 and M4 or M1 and M5 or any set of two parallel interconnects. In some embodiments, COB 300 is formed in metal 2 (M2) and metal 1 (M1) layer region and/or Via 1-2 region.

While the embodiment of FIG. 5 is illustrated with reference to a frontend transistor M1, eDRAM cell can also be formed entirely in the backend. In some embodiments, access transistor M1 of the eDRAM cell may include a back end transistor that is coupled to ferroelectric capacitor 300 by sharing its source/drain terminal with one electrode of ferroelectric capacitor 300 and is used for both READ and WRITE access to ferroelectric capacitor 300.

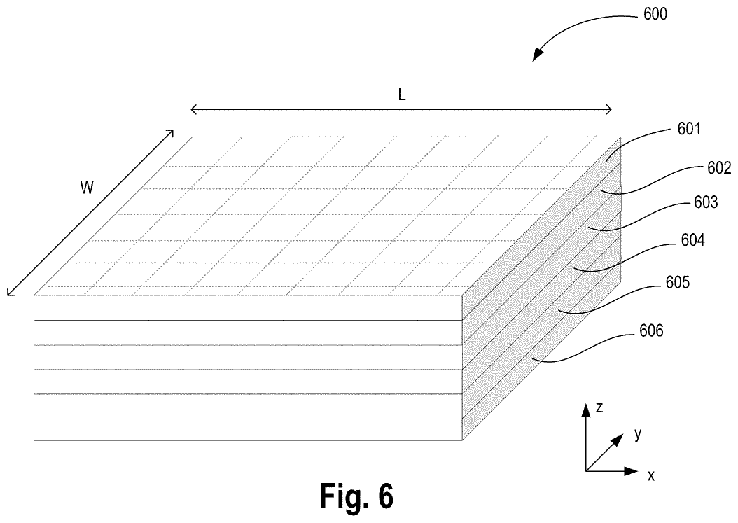

FIG. 6 illustrates apparatus 600, which includes a power plane comprising a super capacitor with insulative oxide layer adjacent to a ferroelectric material, according to some embodiments of the disclosure. In some embodiments, apparatus 600 includes power plane 601, dielectric layer 602, layer of memory 603, dielectric layer 604, ground or sink layer 605. Traditional front-end layer 606 comprises an active region (e.g., a region where a transistor is formed). In some embodiments, power plane 601 provides capacitance such that current or charge delivered by the capacitance is out-of-plane (e.g., perpendicular to the plane of apparatus 600). In some embodiments, by delivering current or charge out-of-plane, high series resistance is avoided in patterned wires (e.g., mesh of wires of power plane 601 shown as dotted lines).

In some embodiments, power plane 601 comprises low-leakage insulating thin film 309 inserted between bottom electrode 401 and ferroelectric oxide 303, between top electrode 402 and ferroelectric oxide 303, or in the middle of ferroelectric oxide 303 to reduce the leakage current. Because of low leakage current passing through Hf and Zr-based oxide layer, there is negligible oxygen vacancies re-distribution, which improve reliability. For perovskite and lead-based oxide, with inserting a low leakage oxide thin film the thickness of perovskite is scaled down while achieving low leakage current. This is an efficient way to control the leakage current without changing the ferroelectric property (memory window and annealing temperature) in ferroelectric oxide.

In some embodiments, power plane 601 is disposed “on” or “over” dielectric layer 602 (e.g., oxide). In some embodiments, a beyond CMOS device layer 603 (e.g., layer comprising spin layer, magnetic logic, magnetic memory, magnetic junction (e.g., spin valve or magnetic tunneling junction), all spin logic (ASL), etc.). In some embodiments, beyond CMOS device layer 603 is adjacent to dielectric layer 604. In some embodiments, dielectric layer 604 is adjacent to a ground plane 605. In some embodiments, ground plane 605 is coupled to layer 606, which includes traditional fabricating layers (e.g., layers used in a CMOS process). In some embodiments, the length ‘L’ and width ‘W’ of power plane 601 is 1 centimeter (cm) each resulting in a 100 mm² area plane which is large enough to provide power to a low voltage device beyond CMOS device formed in layer 603. While FIG. 6 shows layer 601 above layer 603 other orientations are possible. For instance, layer 603 can be above layer 601 or beside layer 601 (e.g., rotating apparatus 600 by 180 or 90 degrees respectively).

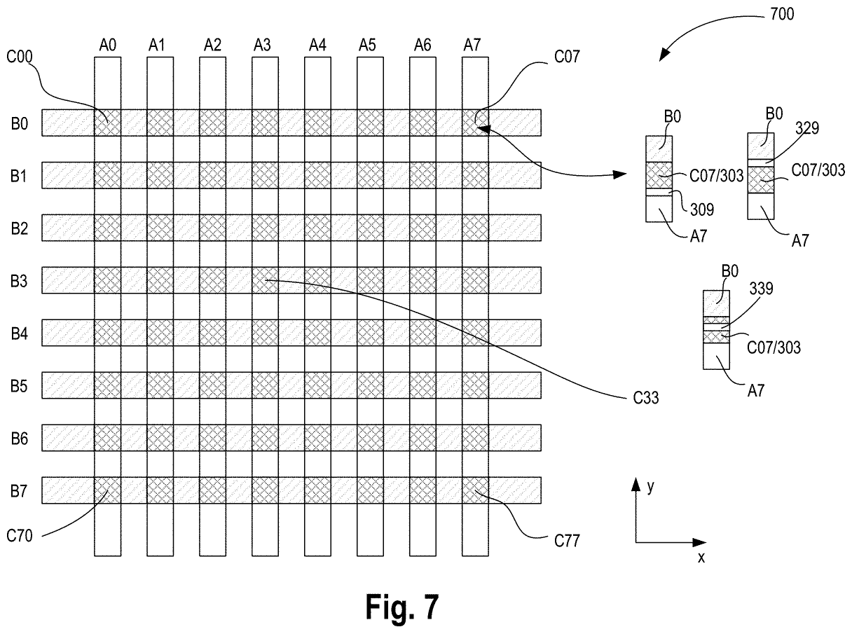

FIG. 7 illustrates apparatus 700 showing distributed MIM capacitors with insulative oxide layer adjacent to a ferroelectric material, according to some embodiments of the disclosure. Apparatus 700 illustrates a mesh of two layers with super capacitor having FE formed between the two layers. In various embodiments, FE material is adjacent to an insulative oxide layer to reduce leakage effects of improve reliance of FE material 303. Here the first layer is layer B having parallel lines B0 through B7, and the second layer is layer A having parallel lines A0 through A7, where lines A0 through A7 are orthogonal to lines B0 through B7. In this example, 8 lines of layers A and B are shown. However, the distributed capacitor of various embodiments can be formed with any number of lines of layers A and B.

In some embodiments, the first layer B with lines B0 through B7 is coupled to a power supply, thus forming power supply lines. In some embodiments, the second layer A with lines A0 through A7 is coupled to a ground supply, thus forming ground supply lines. The array of super capacitors with FE 303 which is adjacent to an insulating oxide layer (e.g., 309) here forms a distributed network of parallel capacitors, in accordance with some embodiments. In some embodiments, super capacitors C00 through C77 (not all are labeled for sake of brevity) are formed between the regions of lines A0 through A7 and B0 through B7. In some embodiments, the super capacitors comprise one of capacitors 300/320/330 or 400/420/430 (shown as a cross-section).

In some embodiments, the array of super capacitors C00 through C77 is used for charge storage and switching in backend of a computing chip. In some embodiments, the array of super capacitors C00 through C77 is integrated with low voltage logic and is used to provide power to it. In some embodiments, the array of super capacitors C00 through C77 provides power to frontend transistors (e.g., CMOS transistors).

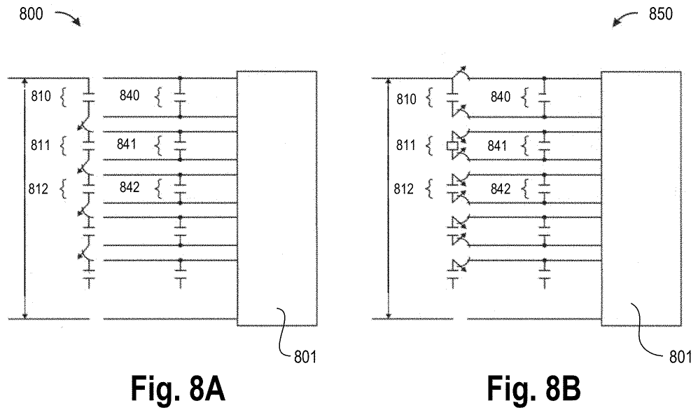

FIGS. 8A-B illustrate apparatuses 800 and 850 and for switch mode power supply during charging and discharging modes, respectively, according to some embodiments of the disclosure. FIG. 8A depicts a charge mode configuration in a SMPS (switch mode power supply) and FIG. 8B depicts a discharge mode configuration in the power supply, in accordance with some embodiments. Elements 840, 841, and 842 represent capacitance (e.g., parasitic capacitance) between layers within the chip, in accordance with some embodiments. In some embodiments, capacitors 810, 811, 812 correspond FE capacitors C00, C01, CO2, etc., which have FE material adjacent to an insulating oxide layer, in accordance with some embodiments. In some embodiments, capacitors 840, 841, 842 and onwards are coupled to power and ground lines of a beyond CMOS device 801 (e.g., spin logic operating on a 10 mV supply). In some embodiments, during the SMPS charging mode, capacitors 810, 811, 812 are charged in series. As shown in configuration 850, switching mechanisms (e.g., circuits) may be configured to convert the SMPS from a series to a parallel connection when switching from charge mode to discharge mode, in which capacitors 810, 811, 812 are discharged in parallel.

The series configured charge mode provides for large voltage division and current multiplication, in accordance with some embodiments. For example, a 1 V power supply applied to charge configuration 800 may be divided down over 100 capacitors to provide 10 mV per capacitor. In place of the charging current of, for example, 1 A (Amperes), each of the capacitors supplies a discharge current of 1 A to create the total current of 100 A over the chip. In some embodiments, the parallel configured discharge mode enables ultra-low series resistance as power need not traverse extended paths and instead deploys out-of-plane directly to a logic device.

In some embodiments, the SMPS includes a charging cycle at, for example, 1 KHz-10 MHz where a bank of FE capacitors is coupled in series to charge to 1 V (FIG. 8A). The FE capacitors comprises low-leakage insulating thin film 309 inserted between bottom electrode 401 and ferroelectric oxide 303, between top electrode 402 and ferroelectric oxide 303, or in the middle of ferroelectric oxide 303 to reduce the leakage current. Because of low leakage current passing through Hf and Zr-based oxide layer, there is negligible oxygen vacancies re-distribution, which improve reliability. For perovskite and lead-based oxide, with inserting a low leakage oxide thin film the thickness of perovskite is scaled down while achieving low leakage current. This is an efficient way to control the leakage current without changing the ferroelectric property (memory window and annealing temperature) in ferroelectric oxide.

In some embodiments, the SMPS includes a discharge cycle at 1 KHz-10 MHz where the capacitors (e.g., each at 10 mV) are discharged in parallel into the device layer. In some embodiments, in order to ensure an uninterrupted power supply, a part of the on-chip capacitors (e.g., C00 through C07) can be in charge mode, while a part of the capacitors (e.g., C10 through C17) can be in discharge mode. Then the SMPS is switched, and charge and discharge modes are reversed. FIGS. 8A-B illustrate how an entire SMPS is located on a chip along with spin logic devices, spintronic memory, and the like. While the SMPS may cooperate with a battery located off chip, the SMPS itself is located on the chip, in accordance with some embodiments.

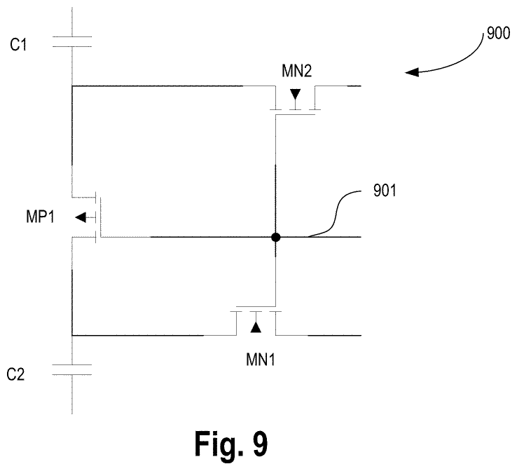

FIG. 9 illustrates a 4-terminal controlled switch 900 for the power plane, according to some embodiments of the disclosure. In some embodiments, the 4-terminal controlled switch comprises p-type transistor MP1, n-type transistors MN1 and MN2, and FE capacitors C1 and C2 coupled together as shown. In some embodiments, the gate terminals of transistors MP1, MN1, and MN2 are coupled to node 901, which provides a switching signal. In some embodiments, capacitors C1 and C2 are according to any one of capacitors 300/320/330 or 400/420/430.

In some examples, the switching element is part of a SMPS embodiment for converting a 1V, 1A supply to a 10 mV, 100 A supply. In some embodiments, transistor MP1 is operative during a clock phase and transistors MN2 and MN2 are operative in an opposite SMPS clock phase.

Some embodiments include the following capacitance per unit area characteristics to enable a low resistance, low power supply that is operative with beyond CMOS devices (e.g., spin logic devices).

In some embodiments, the total charge (Q) required for a chip having an area A=1 mm² with a P_{d}=1 W/cm² power requirement at the spin logic voltage V_{SL}=0.01 V and SMPS switching frequency is 10 MHz is:

$$Q = \frac{{P}_{d} A {T}_{s m p s}}{{V}_{S L}} = 1 {0}^{- 7} C . ,$$

where Tₛₘₚₛ is the period (inverse frequency) of SMPS switching.

The effective capacitance per unit area at a voltage 0.01 V is thus:

$${C}_{d} = \frac{{P}_{d} {T}_{smps}}{{V}_{S L}^{2}} = 1 {0}^{- 3} F . / {cm}^{2} .$$

The required effective capacitance value corresponds to normal capacitance with 10 nm dielectric thickness. An embodiment has a constraint on the dielectric constant, at a dielectric thickness d=10 nm, of:

$$ɛ > \frac{{C}_{d} d}{{ɛ}_{0}} = 1.1$$

This is one option for a dielectric constant. A higher dielectric constant will help relax the requirement for the thickness of the layers, requirement on the area occupied by capacitors, or increase the performance of the power plane.

Some embodiments include a fill factor for the power plane at a given dielectric constant, where the fill factor of the power plane is the total area of the power plane used for the MIM capacitors divided by the chip area. Fill factor for the power plane is given by:

$$F = \frac{{C}_{d} d}{ɛ {ɛ}_{0}}$$

Hence, the fill factors of the supply plane will leave sufficient space for reuse of the metal layer for regular routing or for via dropping.

Some embodiments include a series resistance whereby series resistance seen by the logic device layer is the source resistance of the SMPS at the output. At a fill factor of 10% the series resistance of the via layer per unit chip area is (via resistivity is assumed 10 times copper resistivity):

$${R}_{s} = \frac{ρ L}{F A} \text{∼} 1.6 \times {10}^{- 12} Ω / {cm}^{2} ,$$

where L is length of the via

The effective series resistance voltage drop over the vias is 0.16 nV (which is small compared to the 10 mV supply). At a voltage drop of V_{drop}=1 mV, the required total conductance of the switches per unit chip area:

$${G}_{total} = 3 \frac{{P}_{d}}{{V}_{S L} {V}_{d r o p}} = 3 \times 1 {0}^{5} / ( Ω \cdot {cm}^{2} )$$

The power switching transistors (e.g., transistors MP1, MN1, and MN2) are operated at a low resistance region, below the supply voltage V_{dd}, where the resistance per unit length of the transistors is less than:

$${G}_{STV} = 5 \frac{{I}_{d s a t}}{{V}_{d d}} = 1.4 \times 1 {0}^{4} / ( Ω m ) ,$$

where I_{dsat} is taken from the 2011 edition of the International Technology Roadmap for Semiconductors.

In some embodiments, the total conductance of Gₜₒₜₐₗ requires a gate length per unit area of the chip to be:

$${L}_{gtotal} = \frac{{G}_{total}}{{G}_{S T V}} = \frac{3 {P}_{d} {V}_{d s}}{5 {V}_{S L} {V}_{d r o p} {I}_{sat}} = 21 m \text{/} {cm}^{2}$$

Some embodiments may use a total power transistor gate length of 21 meters to power a 100 mm² chip at 1 W/cm² power budget.

In an embodiment the fraction of area of the power transistors (e.g., transistors MP1, MN1, and MN2) is:

$${F}_{Ptran} = 4 F {L}_{gtotal} = \frac{12 F {P}_{d} {V}_{d s}}{5 {V}_{S L} {V}_{d r o p} {I}_{sat}} = 2.52 \%$$

Hence, the area overhead for power gating and conversion is less than 3%.

In an embodiment, power conversion losses in the SMPS (output delivered power of the SMPS as a fraction of the input power) is as follows:

$${P}_{l o s s} = {I}_{o n} {V}_{d r o p} + \frac{{C}_{Gtotal} {V}_{g}^{2}}{{T}_{smps}}$$

Or in other words:

$${P}_{l o s s} = \frac{{P}_{d} A}{{V}_{S L}} {V}_{d r o p} + \frac{3 {P}_{d} {V}_{d s} {V}_{g}^{2}}{5 {V}_{S L} {V}_{d r o p} {I}_{s a t} {T}_{s m p s}} = 0.1 \; 41 W \text{/} {cm}^{2}$$

and power efficiency of the SMPS is given by:

$${η}_{S M P S} = 1 - \frac{{P}_{l o s s}}{{P}_{d}} = \frac{A}{{V}_{S L}} {V}_{d r o p} + \frac{3 {V}_{d s} {V}_{g}^{2}}{5 {V}_{S L} {V}_{d r o p} {I}_{s a t} {T}_{s m p s}} = 85.88 \%$$

Thus, an embodiment has a power conversion efficiency of 85.88% with an aerial overhead of 2.5% (for a high-k dielectric), on state drop of 1 mV, area fill factor of the power plane of 25%, and current density of 400 A/cm². The series resistance drop is less than 1 nV, thereby avoiding the interconnect losses as outlined in a traditional voltage network.

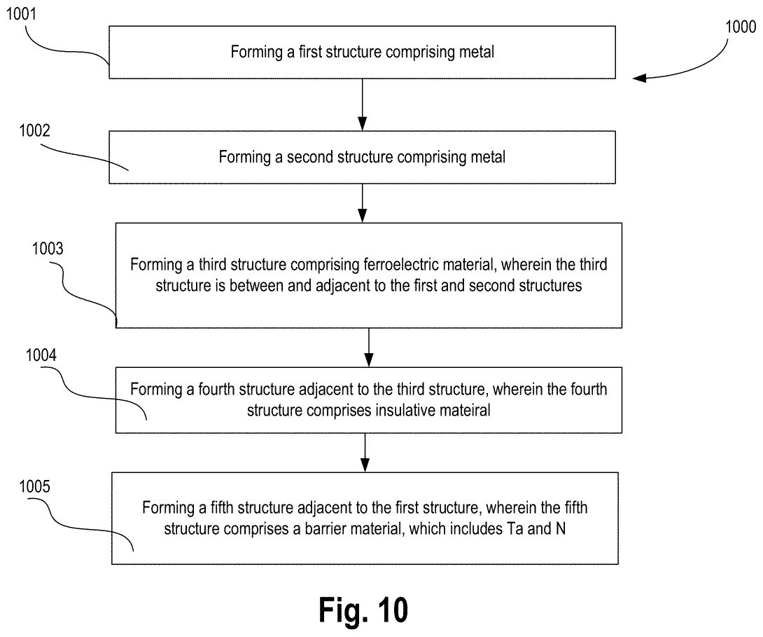

FIG. 10 illustrates flowchart 1000 of a method for forming an FE capacitor with insulative oxide layer adjacent to a ferroelectric material, in accordance with some embodiments of the disclosure, in accordance with some embodiments. While the following blocks (or process operations) in the flowchart are arranged in a certain order, the order can be changed. In some embodiments, some blocks can be executed in parallel.

At block 1001, a first structure (e.g., 301) is formed comprising metal. At block 1002, a second structure (e.g., 302) is formed comprising metal. At block 1003, a third structure (e.g., 303) is formed comprising ferroelectric material, wherein the third structure is between and adjacent to the first and second structures. In some embodiments, the ferroelectric material includes one or more of: Hf or Zr. In some embodiments, the ferroelectric material includes one or more of: Pb, Ti, Zr, Ba, N Si, La, Al, or Hf. In some embodiments, the ferroelectric material has a thickness in a range of 2 nm to 20 nm. In some embodiments, the ferroelectric material is a super lattice of a first material and a second material, wherein the first material includes one of: PbTiO₃ (PTO), SrZrO₃, or FeO3, and wherein the second material includes one of: SrTiO₃ (STO), BaZrO₃, or YTiO₃.

At block 1004, a fourth structure is formed adjacent to the third structure, wherein the fourth structure comprises insulative material. In some embodiments, the insulative material includes an oxide of one or more of: Al, Ti, Hf, Si, Ir, or N. In some embodiments, the insulative material has a thickness in a range of 5 A to 100 A. At block 1005, a fifth structure is formed adjacent to the first structure, wherein the fifth structure comprises a barrier material, which includes Ta and N. In some embodiments, the method comprises forming a sixth structure adjacent to the fifth structure such that the fifth structure is between the first and sixth structures, wherein the sixth structure comprises metal including one or more of: Cu, Al, graphene, carbon nanotube, Au, Co, Ti, N.

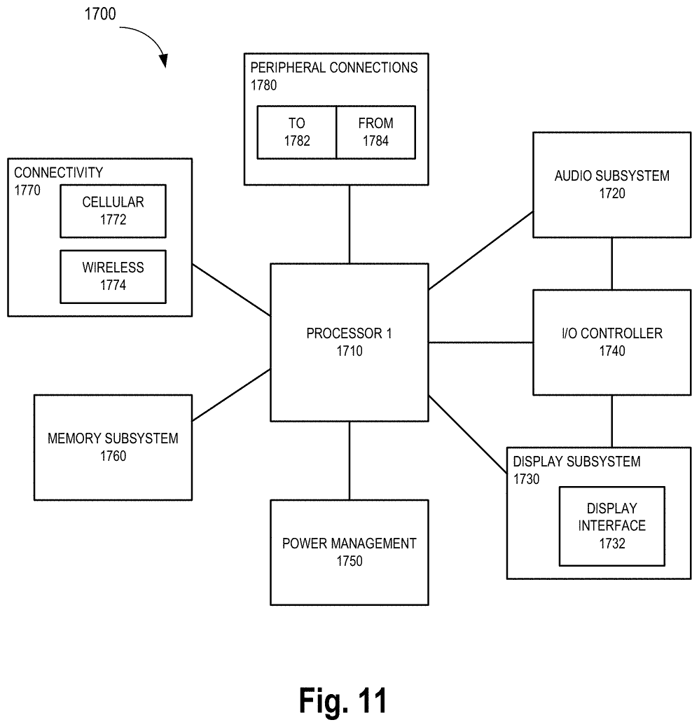

FIG. 11 illustrates a smart device, a computer system, or a SoC (System-on-Chip) including FE capacitor with insulative oxide layer adjacent to a ferroelectric material, in accordance with some embodiments of the disclosure. FIG. 11 illustrates a block diagram of an embodiment of a mobile device in which flat surface interface connectors could be used. In some embodiments, computing device 1700 represents a mobile computing device, such as a computing tablet, a mobile phone or smart-phone, a wireless-enabled e-reader, or other wireless mobile device. It will be understood that certain components are shown generally, and not all components of such a device are shown in computing device 1700.

In some embodiments, computing device 1700 includes first processor 1710 with FE capacitor with insulative oxide layer adjacent to a ferroelectric material (e.g., capacitor 300/320/330 or 400/420/430), according to some embodiments discussed. Other blocks of the computing device 1700 may also include FE capacitor with insulative oxide layer adjacent to a ferroelectric material (e.g., capacitor 300/320/300 or 400/420/430), according to some embodiments. The various embodiments of the present disclosure may also comprise a network interface within 1770 such as a wireless interface so that a system embodiment may be incorporated into a wireless device, for example, cell phone or personal digital assistant.

In some embodiments, processor 1710 can include one or more physical devices, such as microprocessors, application processors, microcontrollers, programmable logic devices, or other processing means. The processing operations performed by processor 1710 include the execution of an operating platform or operating system on which applications and/or device functions are executed. The processing operations include operations related to I/O (input/output) with a human user or with other devices, operations related to power management, and/or operations related to connecting the computing device 1700 to another device. The processing operations may also include operations related to audio I/O and/or display I/O.

In some embodiments, computing device 1700 includes audio subsystem 1720, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1700, or connected to the computing device 1700. In one embodiment, a user interacts with the computing device 1700 by providing audio commands that are received and processed by processor 1710.

In some embodiments, computing device 1700 comprises display subsystem 1730. Display subsystem 1730 represents hardware (e.g., display devices) and software (e.g., drivers) components that provide a visual and/or tactile display for a user to interact with the computing device 1700. Display subsystem 1730 includes display interface 1732, which includes the particular screen or hardware device used to provide a display to a user. In one embodiment, display interface 1732 includes logic separate from processor 1710 to perform at least some processing related to the display. In one embodiment, display subsystem 1730 includes a touch screen (or touch pad) device that provides both output and input to a user.

In some embodiments, computing device 1700 comprises I/O controller 1740. I/O controller 1740 represents hardware devices and software components related to interaction with a user. I/O controller 1740 is operable to manage hardware that is part of audio subsystem 1720 and/or display subsystem 1730. Additionally, I/O controller 1740 illustrates a connection point for additional devices that connect to computing device 1700 through which a user might interact with the system. For example, devices that can be attached to the computing device 1700 might include microphone devices, speaker or stereo systems, video systems or other display devices, keyboard or keypad devices, or other I/O devices for use with specific applications such as card readers or other devices.

As mentioned above, I/O controller 1740 can interact with audio subsystem 1720 and/or display subsystem 1730. For example, input through a microphone or other audio device can provide input or commands for one or more applications or functions of the computing device 1700. Additionally, audio output can be provided instead of, or in addition to display output. In another example, if display subsystem 1730 includes a touch screen, the display device also acts as an input device, which can be at least partially managed by I/O controller 1740. There can also be additional buttons or switches on the computing device 1700 to provide I/O functions managed by I/O controller 1740.

In some embodiments, I/O controller 1740 manages devices such as accelerometers, cameras, light sensors or other environmental sensors, or other hardware that can be included in the computing device 1700. The input can be part of direct user interaction, as well as providing environmental input to the system to influence its operations (such as filtering for noise, adjusting displays for brightness detection, applying a flash for a camera, or other features).

In some embodiments, computing device 1700 includes power management 1750 that manages battery power usage, charging of the battery, and features related to power saving operation. Memory subsystem 1760 includes memory devices for storing information in computing device 1700. Memory can include nonvolatile (state does not change if power to the memory device is interrupted) and/or volatile (state is indeterminate if power to the memory device is interrupted) memory devices. Memory subsystem 1760 can store application data, user data, music, photos, documents, or other data, as well as system data (whether long-term or temporary) related to the execution of the applications and functions of the computing device 1700.

Elements of embodiments are also provided as a machine-readable medium (e.g., memory 1760) for storing the computer-executable instructions (e.g., instructions to implement any other processes discussed herein). The machine-readable medium (e.g., memory 1760) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

In some embodiments, computing device 1700 comprises connectivity 1770. Connectivity 1770 includes hardware devices (e.g., wireless and/or wired connectors and communication hardware) and software components (e.g., drivers, protocol stacks) to enable the computing device 1700 to communicate with external devices. The computing device 1700 could be separate devices, such as other computing devices, wireless access points or base stations, as well as peripherals such as headsets, printers, or other devices.

Connectivity 1770 can include multiple different types of connectivity. To generalize, the computing device 1700 is illustrated with cellular connectivity 1772 and wireless connectivity 1774. Cellular connectivity 1772 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1774 refers to wireless connectivity that is not cellular, and can include personal area networks (such as Bluetooth, Near Field, etc.), local area networks (such as Wi-Fi), and/or wide area networks (such as WiMax), or other wireless communication.

In some embodiments, computing device 1700 comprises peripheral connections 1780. Peripheral connections 1780 include hardware interfaces and connectors, as well as software components (e.g., drivers, protocol stacks) to make peripheral connections. It will be understood that the computing device 1700 could both be a peripheral device (“to” 1782) to other computing devices, as well as have peripheral devices (“from” 1784) connected to it. The computing device 1700 commonly has a “docking” connector to connect to other computing devices for purposes such as managing (e.g., downloading and/or uploading, changing, synchronizing) content on computing device 1700. Additionally, a docking connector can allow computing device 1700 to connect to certain peripherals that allow the computing device 1700 to control content output, for example, to audiovisual or other systems.

In addition to a proprietary docking connector or other proprietary connection hardware, the computing device 1700 can make peripheral connections 1780 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

Following examples illustrates various embodiments. The examples can be combined in any suitable manner.

Example 1: An apparatus comprising: a first structure comprising metal; a second structure comprising metal; a third structure comprising ferroelectric material, wherein the third structure is between and adjacent to the first and second structures; and a fourth structure adjacent to the third structure, wherein the fourth structure comprises insulative material.

Example 2: The apparatus of example 1, wherein the insulative material includes an oxide of one or more of: Al, Ti, Hf, Si, Ir, or N.

Example 3: The apparatus of example 1, wherein the insulative material has a thickness in a range of 5 A to 100 A.

Example 4: The apparatus of example 1 comprising a fifth structure adjacent to the first structure, wherein the fifth structure comprises a barrier material, which includes Ta and N.

Example 5: The apparatus of example 1 comprising a sixth structure adjacent to the fifth structure such that the fifth structure is between the first and sixth structures, wherein the sixth structure comprises metal including one or more of: Cu, Al, graphene, carbon nanotube, Au, Co, Ti, or N.

Example 6: The apparatus of example 1, wherein the ferroelectric material includes one or more of: Hf or Zr.

Example 7: The apparatus of example 1, wherein the ferroelectric material includes one or more of: Pb, Ti, Zr, Ba, N Si, La, Al, or Hf.

Example 8: The apparatus of example 1, wherein the ferroelectric material has a thickness in a range of 2 nm to 20 nm.

Example 9: The apparatus of example 1, wherein the ferroelectric material is a super lattice of a first material and a second material, wherein the first material includes one of: PbTiO₃ (PTO), SrZrO₃, or FeO3, and wherein the second material includes one of: SrTiO₃ (STO), BaZrO₃, or YTiO₃.

Example 10: An apparatus comprising: a bit-line; a word-line; a transistor coupled to the bit-line and the word-line; and a capacitor over the bit-line (COB), wherein the COB is coupled to ground and the transistor, wherein the COB comprises: a first electrode comprising metal; a second electrode comprising metal; a first structure comprising ferroelectric material, wherein the first structure is between and adjacent to the first and second electrodes; and a second structure adjacent to the first structure, wherein the second structure comprises insulative material.

Example 11: The apparatus of example 10, wherein the insulative material includes an oxide of one or more of: Al, Ti, Hf, Si, Ir, or N.

Example 12: The apparatus of example 10, wherein the insulative material has a thickness in a range of 5 A to 100 A.

Example 13: The apparatus of example 10 comprising: a first barrier structure adjacent to the first electrode, wherein the second barrier structure comprises Ta and N; and a second barrier structure adjacent to the second electrode, wherein the second barrier structure comprises Ta and N.

Example 14: The apparatus of example 10 comprising a first interconnect adjacent to the first barrier; and a second interconnect adjacent to the second barrier.

Example 15: The apparatus of example 10, wherein the first and second interconnect comprise metal including one or more of: Cu, Al, graphene, carbon nanotube, Ay, Co, or Ti.

Example 16: The apparatus of example 10, wherein the ferroelectric material includes one or more of: Hf or Zr.

Example 17: A system comprising: a processor; and a memory coupled to the processor, wherein the memory includes: a ferroelectric material between two electrodes; an insulative material adjacent to the ferroelectric material; and a wireless interface to allow the processor to communicate with another device.

Example 18: The system of example 17, wherein the two electrodes comprise metal including one or more of: Cu, Al, graphene, carbon nanotube, Ay, Co, or Ti.

Example 19: The system of example 17 wherein the insulative material includes an oxide of one or more of: Al, Ti, Hf, Si, Ir, or N, and wherein the insulative material has a thickness in a range of 5 A to 100 A.

Example 20: The system of example 17, wherein the ferroelectric material includes oxides of one or more of: Hf or Zr.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An apparatus comprising:
a first structure comprising metal;
a second structure comprising metal;
a third structure comprising ferroelectric material, wherein the third structure is between and adjacent to the first and second structures; and
a fourth structure adjacent to the third structure, wherein the fourth structure comprises insulative material.

2. The apparatus of claim 1, wherein the insulative material includes an oxide of one or more of: Al, Ti, Hf, Si, Ir, or N.

3. The apparatus of claim 1, wherein the insulative material has a thickness in a range of 5 A to 100 A.

4. The apparatus of claim 1 comprising a fifth structure adjacent to the first structure, wherein the fifth structure comprises a barrier material, which includes Ta and N.

5. The apparatus of claim 1 comprising a sixth structure adjacent to the fifth structure such that the fifth structure is between the first and sixth structures, wherein the sixth structure comprises metal including one or more of: Cu, Al, graphene, carbon nanotube, Au, Co, Ti, or N.

6. The apparatus of claim 1, wherein the ferroelectric material includes one or more of: Hf or Zr.

7. The apparatus of claim 1, wherein the ferroelectric material includes one or more of: Pb, Ti, Zr, Ba, N Si, La, Al, or Hf.

8. The apparatus of claim 1, wherein the ferroelectric material has a thickness in a range of 2 nm to 20 nm.

9. The apparatus of claim 1, wherein the ferroelectric material is a super lattice of a first material and a second material, wherein the first material includes one of: PbTiO₃ (PTO), SrZrO₃, or FeO3, and wherein the second material includes one of: SrTiO₃ (STO), BaZrO₃, or YTiO₃.

10. An apparatus comprising:
a bit-line;
a word-line;
a transistor coupled to the bit-line and the word-line; and
a capacitor over the bit-line (COB), wherein the COB is coupled to ground and the transistor, wherein the COB comprises:
a first electrode comprising metal;
a second electrode comprising metal;
a first structure comprising ferroelectric material, wherein the first structure is between and adjacent to the first and second electrodes; and
a second structure adjacent to the first structure, wherein the second structure comprises insulative material.

11. The apparatus of claim 10, wherein the insulative material includes an oxide of one or more of: Al, Ti, Hf, Si, Ir, or N.

12. The apparatus of claim 10, wherein the insulative material has a thickness in a range of 5 A to 100 A.

13. The apparatus of claim 10 comprising:
a first barrier structure adjacent to the first electrode, wherein the second barrier structure comprises Ta and N; and
a second barrier structure adjacent to the second electrode, wherein the second barrier structure comprises Ta and N.

14. The apparatus of claim 10 comprising a first interconnect adjacent to the first barrier; and
a second interconnect adjacent to the second barrier.

15. The apparatus of claim 10, wherein the first and second interconnect comprise metal including one or more of: Cu, Al, graphene, carbon nanotube, Ay, Co, or Ti.

16. The apparatus of claim 10, wherein the ferroelectric material includes one or more of: Hf or Zr.

17. A system comprising:
a processor; and
a memory coupled to the processor, wherein the memory includes:
a ferroelectric material between two electrodes;
an insulative material adjacent to the ferroelectric material; and
a wireless interface to allow the processor to communicate with another device.

18. The system of claim 17, wherein the two electrodes comprise metal including one or more of: Cu, Al, graphene, carbon nanotube, Ay, Co, or Ti.

19. The system of claim 17 wherein the insulative material includes an oxide of one or more of: Al, Ti, Hf, Si, Ir, or N, and wherein the insulative material has a thickness in a range of 5 A to 100 A.

20. The system of claim 17, wherein the ferroelectric material includes oxides of one or more of: Hf or Zr.
